(19) United States
(12) Patent Application Publication
(10) Pub. No.: US 2014/0042627 A1
(43) Pub. Date: Feb. 13, 2014

(54) ELECTRONIC STRUCTURE CONTAINING A VIA ARRAY AS A PHYSICAL UNCLONABLE FUNCTION

(71) Applicants: Daniel C. Edelstein, White Plains, NY (US); Gregory M. Fritz, Yorktown Heights, NY (US); Stephen M. Gates, Ossining, NY (US); Dirk Pfeiffer, Croton on Hudson, NY (US)

(72) Inventors: Daniel C. Edelstein, White Plains, NY (US); Gregory M. Fritz, Yorktown Heights, NY (US); Stephen M. Gates, Ossining, NY (US); Dirk Pfeiffer, Croton on Hudson, NY (US)

(73) Assignee: INTERNATIONAL BUSINESS MACHINES CORPORATION, Armonk, NY (US)

(21) Appl. No.: 13/570,968

(22) Filed: Aug. 9, 2012

(51) Int. Cl. H01L 23/535; H01L 21/768

(52) U.S. Cl. 257/758; 257/773; 438/637; 257/E23.168; 257/E21.59

(57) ABSTRACT

A secure electronic structure is provided including a via array as a physical unclonable function (PUF). Specifically, the secure electronic structure includes an array of electrical contact vias located between a lower level of a first regularly spaced array of conductors and an upper level of a second regularly spaced array of conductors. Each electrical contact via of the via array is individually addressed through the first regularly spaced array of conductors in the lower level and the second regularly spaced array of conductors in the upper level and has a resistance value. Each resistance value of each electrical contact via forms a distribution of resistance values, wherein the distribution of resistance values is random. This random distribution of the resistance values of the array of electrical contact vias can be used as a physical unclonable function in the electronic structure of the present disclosure.

### BACKGROUND

The present disclosure relates to a secure electronic structure, an integrated circuit which includes the secure electronic structure and methods of forming the same. More particularly, the present disclosure relates to an electronic structure containing a via array as a physical unclonable function.

In the electronics industry, security in an electronic device has become a major concern of manufacturers and users of such devices. In this regard, it is useful to be able to distinguish each electronic device, especially the integrated circuit within these devices, from each other. This is particularly true for devices such as computers, personal hand held devices, cellular phones, chip cards, and other devices that contain sensitive information. Developers of electronic devices continuously strive to provide systems and methods that make their products impervious to unauthorized access or use.

At the same time, most applications have cost limitations that must be taken into account. For example, if a complicated authentication process requiring storage and computing resources were employed on an integrated circuit, the costs incurred may not justify the cost of security accomplished, particularly if the end product were a low cost and mass produced consumer product.

According to the prior art, a key in a binary code may be stored on a secure integrated circuit in a non-volatile memory array on the circuit. At initialization of the circuit (boot up), the authorized user inputs a code, and initialization (boot up) continues only if the correct code is entered. The secure circuit does not function without the correct code entered at the correct step. However, the circuit may be physically delayered by an unauthorized user (e.g., an enemy) and the binary code obtained by reading the individual device states in the non-volatile memory array. The circuit is then not secure and can be used by the unauthorized user, and the system security has been broken.

One approach to solve the above identified problems is to employ a physical unclonable function (PUF) to provide a unique, secure bit, word or function for use in generating security keys. A PUF may eliminate the need for storage of a public or private key on a device. PUFs are known in the art to be implemented by circuits, components, processes or other entities capable of generating an output, such as a digital bit, word or a function that is resistant to cloning.

Typically, the PUF can be generated based on inherent physical characteristics of a device such as for example individual physical characteristics of a transistor such as a threshold voltage of the transistor which varies due to local process variations during manufacturing. There is no need to store the PUF within the device, because the PUF can be generated repeatedly. Moreover, it is nearly impossible to clone a device having a PUF implemented in a manner to generate the same PUF output with another device.

Although PUFs have been implemented within electronic devices, there exists a need to create an electronic structure having a physical unclonable function embodied in the physical structure, which is easy to evaluate but hard to predict, and which is formed using standard integrated circuit manufacturing methods and materials. It is desirable to fabricate the PUF during standard integrated circuit manufacturing and to add a minimum number of additional process steps in order to complete the PUF structure, so the PUF is inexpensive to manufacture.

It is desirable to have a system or method of storing a code on the secure integrated circuit that is randomly generated.

### SUMMARY

Embodiments of the present disclosure describe secure integrated circuits, physical unclonable function structures, and methods to make such structures and circuits.

In one embodiment, the present disclosure provides a secure electronic structure including a via array as a physical unclonable function (PUF) and an integrated circuit including the same. Specifically, the secure electronic structure of the present disclosure includes an array of electrical contact vias located between a lower level of a first regularly spaced array of conductors and an upper level of a second regularly spaced array of conductors. Each electrical contact via of the array of electrical contact vias is individually addressed through the first regularly spaced array of conductors in the lower level and the second regularly spaced array of conductors in the upper level and has a resistance value. In one embodiment, each resistance value of each electrical contact via can be combined into a distribution of resistance values, wherein the distribution of resistance values is random. This random distribution of the resistance values of the array of electrical contact vias can be used as a physical unclonable function in the electronic structure of the present disclosure.

In a second embodiment, the location of each electrical contact via is described as a matrix, and the matrix location of the high and low resistance values of each electrical contact via is randomly generated and can be used as the physical unclonable function in the electronic structure of the present disclosure.

In one aspect of the present disclosure, an electronic structure including a physical unclonable function is provided. The electronic structure of the present disclosure includes a first level including a first regularly spaced array of conductors. The structure further includes a second level including a plurality of electrical contact vias atop the first level. The structure also includes a third level including a second regularly spaced array of conductors atop the second level. In accordance with the present disclosure, each electrical contact via of the plurality of electrical contact vias in the second level is individually addressed through the first regularly spaced array of conductors in the first level and the second regularly spaced array of conductors in the third level and has a resistance value. Each resistance value of each electrical contact via in the second level forms a distribution of resistance values, wherein the distribution of resistance values is random.

In another aspect of the present disclosure, an integrated circuit is provided that includes an electronic structure having a physical unclonable function. The integrated circuit of the present disclosure includes at least one semiconductor device located upon a portion of a semiconductor substrate. In some embodiments, measurement circuits are included on the substrate to measure the resistance of each via in the via array. A first level including a first regularly spaced array of conductors is located atop the semiconductor substrate including the at least one semiconductor device. The integrated circuit further includes a second level including a plurality of electrical contact vias atop the first level. The integrated circuit also includes a third level including a second regularly spaced array of conductors atop the second level. In accordance with the present disclosure, each electrical contact via of the plurality of electrical contact vias in the second level is individually addressed through the first regularly spaced array of conductors in the first level and the second regularly spaced array of conductors in the third level and has a resistance value. Each resistance value of each electrical contact via in the second level forms a distribution of resistance values, wherein the distribution of resistance values is random.

In another aspect of the present disclosure, methods of forming an electronic structure including a physical unclonable function are provided. Each method of the present disclosure includes forming a first level comprising a first regularly spaced array of conductors embedded within a first dielectric material. Next, a second level comprising a plurality of electrical contact vias embedded within a second dielectric material is formed atop the first level. In accordance with the present disclosure, each electrical contact via of the plurality of electrical contact vias has a resistance value, wherein each resistance value of each electrical contact via forms a distribution of resistance values, and wherein the distribution of resistance values is random. Also, the matrix location of high and low resistance values of each electrical contact via in the array is random. Next, a third level comprising a second regularly spaced array of conductors is formed atop the second level, wherein each electrical contact via of the plurality of electrical contact vias in the second level is individually addressed through the first regularly spaced array of conductors in the first level and the second regularly spaced array of conductors in the third level.

### BRIEF DESCRIPTION OF THE DRAWINGS

FIG. 1 is a three-dimensional (3D) pictorial representation of an electronic structure in accordance with an embodiment of the present disclosure.

FIG. 2 is schematic of an electronic structure with a physical unclonable function based on random resistance (R) values of the array or matrix of electrical contact vias in accordance with an exemplary embodiment of the present disclosure.

FIG. 3 is a pictorial representation (through a cross sectional view) illustrating an initial structure including a first level comprising a first regularly spaced array of conductors located within a first dielectric material that can be used in one embodiment of the present disclosure.

FIG. 4 is a pictorial representation (through a cross sectional view) depicting the structure of FIG. 3 after forming a second dielectric material atop the first level.

FIG. 5 is a pictorial representation (through a cross sectional view) depicting the structure of FIG. 4 after forming an etch mask including an array of openings atop the second dielectric material.

FIG. 6 is a pictorial representation (through a cross sectional view) depicting the structure of FIG. 5 after forming a diblock copolymer layer atop the etch mask.

FIG. 7 is a pictorial representation (through a cross sectional view) depicting the structure of FIG. 6 after removing one of the polymeric block components of the diblock copolymer layer.

FIG. 8 is a pictorial representation (through a cross sectional view) depicting the structure of FIG. 7 after transferring a mask pattern into the second dielectric material.

FIG. 9 is a pictorial representation (through a cross sectional view) depicting the structure of FIG. 8 after removing remaining portions of the diblock copolymer and the etch mask from atop the now patterned second dielectric material.

FIG. 10 is a pictorial representation (through a cross sectional view) depicting the structure of FIG. 9 after filling the vias within the second dielectric material with an electrical conductive material and planarizing.

FIG. 11 is a pictorial representation (through a cross sectional view) depicting the structure of FIG. 10 after forming a third level including a second regularly spaced array of conductors atop the second dielectric material.

FIG. 12A a pictorial representation (through a cross sectional view) depicting the structure of FIG. 4 after forming a photoresist atop the second dielectric material and performing a first lithographic step which creates a first pattern in individual first regions of the photoresist.

FIG. 12B is a top down view of the structure depicted in FIG. 12A.

FIG. 13 a pictorial representation (through a top down view) depicting the structure of FIGS. 12A-12B after performing a second lithographic step which creates a second pattern in individual second regions of the photoresist using a same mask as the first lithographic step but rotated by 90°-delta.

### DETAILED DESCRIPTION

The present disclosure, which provides a secure electronic structure with a physical unclonable function (PUF), an integrated circuit including the secure electronic structure and methods of fabricating the same, will now be described in greater detail by referring to the following discussion and drawings that accompany the present application. It is noted that the drawings of the present application are provided for illustrative purposes and, as such, they are not drawn to scale. In the drawings and the description that follows, like elements are referred to by like reference numerals. For purposes of the description hereinafter, the terms “upper”, “lower”, “right”, “left”, “vertical”, “horizontal”, “top”, “bottom”, and derivatives thereof shall relate to the components, layers and/or elements as oriented in the drawing figures which accompany the present application.

In the following description, numerous specific details are set forth, such as particular structures, components, materials, dimensions, processing steps and techniques, in order to provide a thorough understanding of the present invention. However, it will be appreciated by one of ordinary skill in the art that the present disclosure may be practiced with viable alternative process options without these specific details. In other instances, well-known structures or processing steps have not been described in detail in order to avoid obscuring the various embodiments of the present disclosure.

As stated above and in some embodiments of the present disclosure, a secure electronic device and an integrated circuit that includes the same are provided. More particularly, the present disclosure provides an electronic structure in which a code for authentication is stored directly on the integrated circuit itself, using a unique physical identifier (or code) fabricated within the electronic structure. The secure electronic structure of the present disclosure retains the unique code, and is generated randomly.

In the present disclosure, the electronic structure remains stable when the electronic structure is powered down, because it is hidden in the form of unique identifiers (i.e., PUFs) within the electronic structure itself. A unique physical identifier or fingerprint thus can exist on every chip due to inherently random variations. These random variations can be utilized as a unique physical identifier of each integrated circuit and must be matched with an input code when the circuit is initialized.

The electronic structure of the present disclosure which includes the PUF can be made utilizing standard semiconductor manufacturing methods and materials, while utilizing a minimum of added processing steps. Also, the electronic structure of the present disclosure has the following characteristics: (i) reliability to avoid bit errors: The electronic structure of the present disclosure is stable and the PUF value does not drift significantly over time and temperature and circuit use. (ii) Random variability: Variability of the electronic structure of the present disclosure is significant enough to enroll millions of electronic structures to give each a unique code and the PUF values are random to avoid would be attackers, i.e., unauthorized users, from guessing specific patterns. Variability is also important to the PUF stability to avoid bit errors.

As stated above, the electronic structure includes an array of electrical contact vias located between a lower level of a first regularly spaced array of conductors and an upper level of a second regularly spaced array of conductors. Each electrical contact via has a resistance value which can be addressed and measured. Each resistance value of each electrical contact via forms a distribution of resistance values, wherein the distribution of resistance values is random. This random distribution of the resistance values of the array of electrical contact vias can be used as a physical unclonable function.

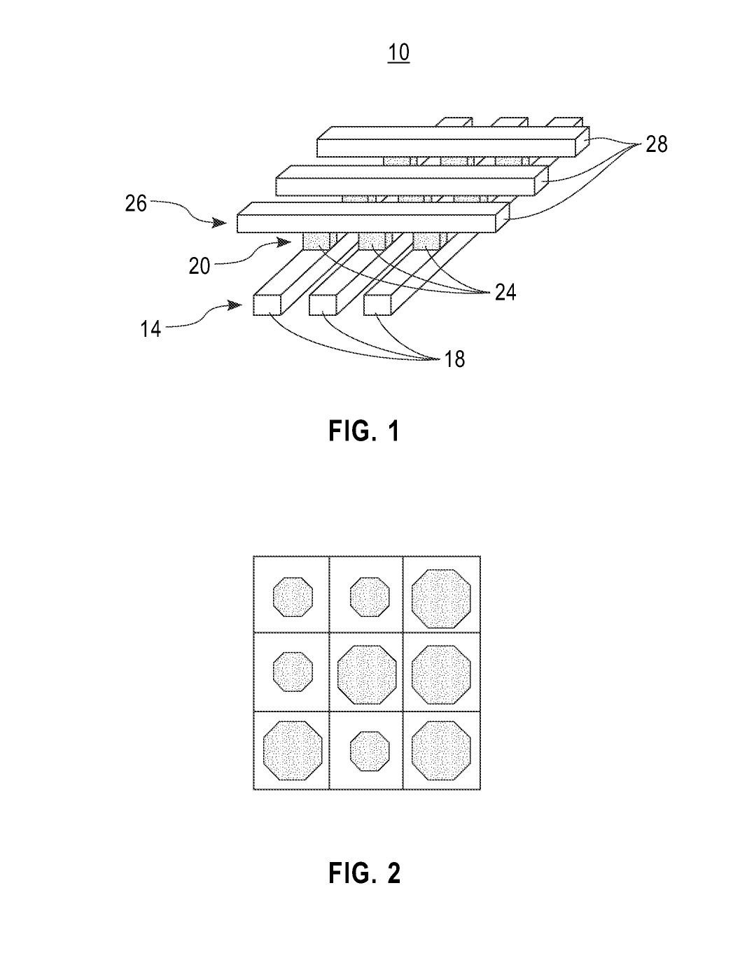

Referring now to FIG. 1, there is depicted an electronic structure 10 with a PUF function embodied therein in accordance with an embodiment of the present disclosure. Specifically, the electronic structure 10 shown in FIG. 1 includes a first level 14 including a first regularly spaced array of conductors 18. The structure 10 further includes a second level 20 including a plurality of electrical contact vias 24 atop the first level 14. The structure 10 also includes a third level 26 including a second regularly spaced array of conductors 28 atop the second level 20. In this drawing, the first regularly spaced array of conductors 18 are typically embedded within a first dielectric material, and the plurality of electrical contact vias 24 are typically embedded within a second dielectric material. The first and second dielectric materials are not shown in the drawing that is represented by FIG. 1.

In accordance with the present disclosure, each electrical contact via of the plurality of electrical contact vias 24 in the second level 20 can be individually addressed through the first regularly spaced array of conductors 18 in the first level 14 and the second regularly spaced array of conductors 28 in the third level 26. Also, each electrical contact via of the plurality of electrical contact vias 24 has a resistance value. In one embodiment, each resistance value of each electrical contact via contributes to a distribution of resistance values, wherein the distribution of resistance values is random. In a second embodiment, each resistance value of each electrical contact via has a specific location described as a matrix and the code consists of a 0 or 1 value at each location, or matrix cell.

Structure 10 is an example of a crossbar array, which is a widely used general structure, for example, in resistive memory arrays. There exists a body of prior art describing circuits to individually address and read each location in a crossbar array where an upper conductor (in level 26) intersects a lower conductor (in level 14), and circuits performing this function are well known. One example is described in U.S. Pat. No. 7,564,262 B2, which also lists several prior art patents. In one embodiment, a demultiplexer such as disclosed, for example, in U.S. Pat. No. 6,256,767, and the publication entitled “Nanoelectronics from the bottom up” Nature Materials, vol. 6, Nov. 2007, can be used to address and read the electronic structure of the present disclosure. In some embodiments, the demultiplexer can be wired to any of the first regularly spaced array of conductors 18 and/or the second regularly spaced array of conductors 28.

As shown in the various drawings of the present disclosure, each conductor of the second regularly spaced array of conductors 28 has a bottommost surface that is in direct contact with an uppermost surface of an electrical contact via of the plurality of electrical contact vias 24. Also, each conductor of the first regularly spaced array of conductors 18 has an uppermost surface that is in direct contact with a bottommost surface of an electrical contact via of the plurality of electrical contact vias 24.

The randomness of the resistance value of each electrical contact via of the plurality of contact vias 24 can be used herein as a PUF and thus can be used as a security code for the electronic structure of the present disclosure. Each individual via has a resistance value, and the table of resistance and location can thus be referred to as a PUF value, which remains in the electronic device during power on and power off states. When an electronic device containing the electronic structure of the present disclosure is powered on, the user can input the correct code into the system, the circuit compares the input code with that stored on the circuit. For correct matches of the code, the electronic device boots up to its normal function. When no code or an incorrect is inputted during powering on the electronic device containing the electronic structure of the present disclosure, the electronic device is disabled (boot up stops) preventing the user from obtaining access to the system.

Referring now to FIG. 2, there is shown an electronic structure with a physical unclonable function based on random resistance (R) values in the electrical contact vias in accordance with an exemplary embodiment of the present disclosure. In this exemplary embodiment, an array of electrical contact vias in nine cells is shown. The large diameter octagons represent electrical contact vias with a large contact area and hence a small resistance. The smaller diameter octagons represented electrical contact vias with a small contact area, and hence a large resistance. The resistance values can be measured for each of the N electrical contact vias within the array utilizing any conventional device which contains circuits to address and read the resistance value at each location. For example, circuitry known in the art can be used to address and read the resistance value of each electrical contact via within the plurality of electrical contact vias. The measured resistance values can be assigned into groups (i.e., bins) to represent the digital 0 or 1. In the embodiment illustrated, the number of configurations in the digital identifier is 2̂N, wherein N is 9. In alternative embodiments, more groups of resistance bins can be used to represent 0, 1, 2, 3, etc. For example, with 4 levels of resistance bins, the number of configuration in the digital identifier can be represented by 4̂N for N vias. Thus, the present disclosure is not limited to any number of electrical contact vias in the structure.

As shown in FIG. 2, vias are shown in top down view, and vias with different diameter are shown. More generally, the vias can be any shape in the top down view, and each electrical contact via has a characteristic dimension with the dimensions of length, e.g., nanometers. For a circle, the diameter is the characteristic dimension, while for other shapes the characteristic dimension is a measure of the top down area.

The electronic structure 10 that shown in FIG. 1 can be formed atop a semiconductor substrate including at least one semiconductor device, i.e., transistor, resistor, capacitor, diode, and BiCMOS, located thereon providing an integrated circuit of the present disclosure. The electronic structure 10 that is shown in FIG. 1 is conveniently fabricated during standard BEOL interconnect processing. This aspect of the present disclosure will become more apparent in the description of the various methods that can be used in the present disclosure in forming the electronic structure illustrated in FIG. 1. In some embodiments, measurement circuits are included on the substrate to measure the resistance of each array.

The various methods that can be employed in the present disclosure are now disclosed together with specific details regarding the materials that can be employed in the present disclosure in forming the electronic structure shown in FIG. 1.

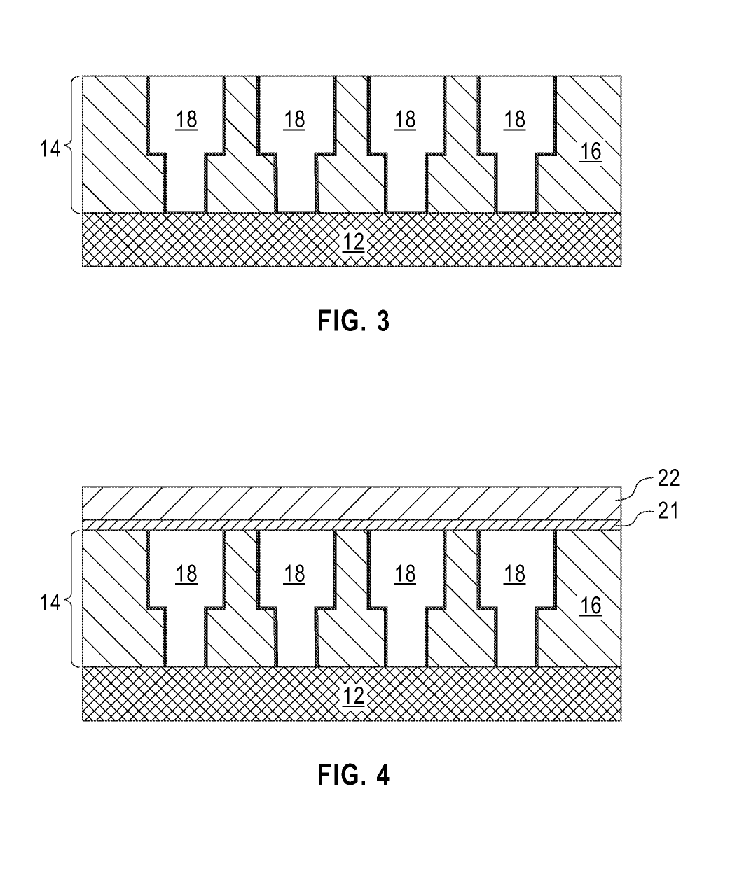

Referring first to FIG. 3, there is depicted an initial structure including a first level 14 comprising a first regularly spaced array of conductors 18 located within a first dielectric material 16. The first level 14 is formed atop a substrate 12.

The substrate 12 may comprise a semiconducting material, an insulating material, a conductive material or any combination including multilayers thereof. When the substrate 12 is comprised of a semiconducting material, any semiconductor such as, for example, Si, SiGe, SiGeC, SiC, Ge alloys, GaAs, InAs, InP and other III/V or II/VI compound semiconductors may be used. In addition to these listed types of semiconducting materials, the present disclosure also contemplates cases in which the semiconductor substrate is a layered semiconductor such as, for example, Si/SiGe, Si/SiC, silicon-on-insulators (SOIs) or silicon germanium-on-insulators (SGOIs). In some embodiments of the present disclosure, the semiconducting material may include one or more semiconductor devices formed thereon. For clarity the one or more semiconductor devices are not shown in the drawings.

When the substrate 12 is an insulating material, the insulating material can be an organic insulator, an inorganic insulator or a combination thereof including multilayers. When the substrate 12 is a conducting material, the substrate may include, for example, polySi, an elemental metal, alloys of elemental metals, a metal silicide, a metal nitride or combinations thereof including multilayers. When the substrate 12 comprises a combination of an insulating material and a conductive material, the substrate may represent one of interconnect levels which can positioned beneath the electronic structure of the present disclosure.

The first dielectric material 16 of the initial structure may include any interlevel or intralevel dielectric material including inorganic dielectrics and/or organic dielectrics. The first dielectric material 16 may be porous, non-porous or contain regions and/or surfaces that are porous and other regions and/or surfaces that may be non-porous. Some examples of suitable dielectrics that can be used as the first dielectric material 16 include, but are not limited to, silicon oxide, silsesquioxanes, C doped oxides (i.e., organosilicates) that include atoms of Si, C, O and H (called “SiCOH” materials), SiCOH materials containing porosity, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. In one embodiment, the first dielectric material 16 has a dielectric constant that is less than silicon oxide, i.e., less than 4.0. In another embodiment, first dielectric material 16 that can be employed in the present disclosure has a dielectric constant of 3.0 or less. All dielectric constants mentioned herein are relative to a vacuum, unless otherwise noted. Dielectrics which have a dielectric constant of less than that of silicon oxide generally have a lower parasitic cross talk as compared with dielectric materials that have a higher dielectric constant equal to, or greater than, silicon oxide. Generally, silicon oxide has a dielectric constant of 4.0.

In one embodiment, the first dielectric material 16 has a thickness from 50 nm to 1000 nm. In other embodiments, the first dielectric material 16 can have a thickness that is greater than or less than the thickness range mentioned above. The first dielectric material 16 can be formed utilizing a deposition process such as, for example, chemical vapor deposition (CVD), plasma enhanced chemical vapor deposition (PECVD), evaporation, chemical solution deposition and spin-on coating.

After providing the first dielectric material 16, a plurality of openings can be formed into the first dielectric material 16. The plurality of openings may include a via opening, a line opening, a combined via and line opening, or any combination thereof. A via opening can be distinguished from a line opening in that the via opening has a narrower width than the line opening. In the particular embodiment illustrated in the drawings, a plurality of combined via and line openings are formed. In accordance with the present disclosure, the plurality of openings that are formed into the first dielectric material 16 are regularly spaced. By “regularly spaced” it is meant that the distance between a center point of one opening to a center point of a nearest neighboring opening is uniform and has a same value, known as the pitch.

The plurality of openings can formed by lithography and etching. When combined via and line openings are formed, a second iteration of lithography and etching can be used to form the same. The lithographic step may include forming a photoresist (organic, inorganic or hybrid) atop the first dielectric material 16. The photoresist can be formed utilizing a deposition process such as, for example, CVD, PECVD and spin-on coating. Following formation of the photoresist, the photoresist can be exposed to a desired pattern of radiation. Next, the exposed photoresist can be developed utilizing a conventional resist development process. After the development step, an etching step can be performed to transfer the pattern from the patterned photoresist into the first dielectric material 16. In one embodiment, a hard mask material such as, for example, titanium nitride and/or silicon nitride or silicon oxide, can be formed atop the first dielectric material 16 prior to forming the photoresist. In such an embodiment, the pattern may be first transferred into the hard mask material and then into the first dielectric material 16. In such an embodiment, the patterned photoresist is typically, but not necessarily always, removed from the surface of the structure after transferring the pattern into the hard mask material utilizing a resist stripping process such as, for example, ashing. The etching step used in forming the plurality of openings may include a dry etching process (including, for example, reactive ion etching, ion beam etching, plasma etching or laser ablation), a wet chemical etching process or any combination thereof. In one embodiment, reactive ion etching is used to form the plurality of openings.

Next, a diffusion barrier liner and a first conductive material are formed within each of the plurality of openings. The diffusion barrier liner (not shown) lines the wall portions within each opening and is thus positioned between the first dielectric material and the first conductive material. The first conductive material that is formed into each opening of the plurality of openings formed in the first dielectric material 16 provides the first regularly spaced array of conductors 18.

The diffusion barrier liner can include any material that can serve as a barrier to prevent conductive material ions from diffusing into the first dielectric material 16. Examples of materials that can be used as the diffusion barrier liner include, for example, Ta, TaN, Ti, TiN, Ru, RuN, RuTa, RuTaN, IrTa, IrTaN, W, WN or a multilayered stack thereof. In one embodiment, the diffusion barrier liner has a thickness from 2 nm to 50 nm. In other embodiment, the diffusion barrier liner has a thickness from, with a thickness from 7 nm to 20 nm. The diffusion barrier liner can be formed by a deposition process including, for example, CVD, PECVD, physical vapor deposition (PVD), sputtering and plating.

The first conductive material includes for example, a conductive metal, an alloy comprising at least two conductive metals, a conductive metal oxide, a conductive metal nitride, a conductive metal silicide or any combination thereof. In one embodiment, the first conductive material can comprise Al, Ti, TiN, Ta, TaN, W, WN, MoN, Pt, Pd, Os, Ru, IrO₂, ReO₂, ReO₃, or Cu. Mixtures or alloys of these conductive materials can also be employed in the present disclosure. The first conductive material can be formed by a deposition process including, for example, CVD, PECVD, PVD, sputtering, plating, chemical solution deposition and electroless plating.

After deposition of each of the diffusion barrier liner and the first conductive material, any excess diffusion barrier material and first conductive material that is located outside of each of the plurality of openings can be removed by a planarization process. In one embodiment, the planarization process includes chemical mechanical polishing (CMP). In another embodiment, the planarization process includes grinding. In a further embodiment, the planarization process includes a combination of CMP and grinding. In some embodiments and when a hard mask material is employed, the planarization process also removes remaining portions of the hard mask material that are located outside each of the plurality of opening and on the upper surface of first dielectric material 16.

Referring now to FIG. 4, there is illustrated the structure of FIG. 3 after forming a second dielectric material 22 as a blanket layer atop the first level 12. In one embodiment, the second dielectric material 22 employed in the present disclosure can include one of the dielectric materials mentioned above for the first dielectric material 16. In another embodiment, silicon nitride and/or silicon oxynitride can be used as the material for the second dielectric material 22. In one embodiment, the second dielectric material 22 comprises a same dielectric material as that of the first dielectric material 16. In another embodiment, the second dielectric material 22 may comprise a different dielectric material as the first dielectric material 16. The second dielectric material 22 can have a thickness within the range mentioned above for the first dielectric material 16, and one of the techniques mentioned above for forming the first dielectric material 16 can be used here to form the second dielectric material 22.

In some embodiments, and as illustrated in FIG. 4, a dielectric cap 21 can be formed atop the first level 12 prior to forming the second dielectric material 22. The dielectric cap 21 that can be employed in some embodiments of the present disclosure includes any suitable dielectric capping material with diffusion barrier properties including, for example, SiC, Si₄NH₃, SiO₂, a carbon doped oxide, a nitrogen and hydrogen doped silicon carbide SiC(N,H) or multilayers thereof. The dielectric cap 21 can be formed by a deposition process such as, for example, chemical vapor deposition, plasma enhanced chemical vapor deposition, chemical solution deposition, evaporation, and atomic layer deposition. The thickness of the dielectric cap 21 may vary depending on the technique used to form the same as well as the material make-up of the layer. Typically, the dielectric cap 21 has a thickness from 15 nm to 100 nm.

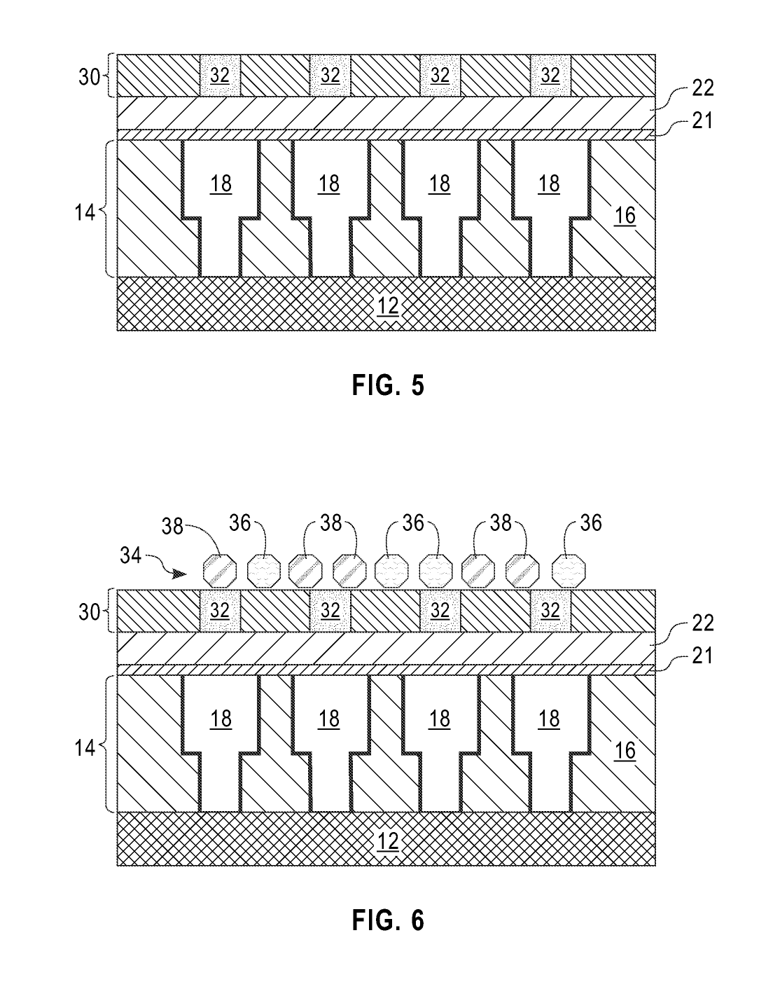

Referring now to FIG. 5, there is depicted the structure of FIG. 4 after forming an etch mask 30 including an array of openings 32 atop the second dielectric material 22. Etch mask 30 includes any dielectric material having an etch selectivity that differs from the second dielectric material 22. Examples of suitable dielectric materials that can be used as etch mask 30 include silicon oxide, silicon nitride, silicon oxynitride, or any multilayered combination thereof. The etch mask 30 can be formed by a deposition process such as, for example, chemical vapor deposition, plasma enhanced chemical vapor deposition, and chemical solution deposition. Alternatively, the etch mask 30 can be formed by a thermal technique such as, for example, oxidation and/or nitridation. The thickness of the etch mask 30 can vary depending on the materials of the etch mask 30 itself and the technique used to form the same. Typically, the etch mask 30 has a thickness from 10 nm to 500 nm.

The array of openings 32 can be formed by lithography and etching as described above for forming the plurality of openings within the first dielectric material 16. Each opening of the array of openings 32 is located atop a conductor of the first regularly spaced array of conductors 18. The array of openings 32 that are formed at this point of the present disclosure are regular spaced as shown in the drawings. The term “regularly spaced” has the same meaning as mentioned above.

Referring now to FIG. 6, there is depicted the structure of FIG. 5 after forming a diblock copolymer layer 34 atop the etch mask 30. The diblock copolymer layer 34 employed in the present disclosure includes a self-assembling block copolymer that is capable of self-organizing into nanometer-scale patterns. Under suitable conditions, two or more immiscible polymeric block components separate into two or more different phases on a nanometer scale and thereby form ordered patterns of isolated nano-sized structural units. Such ordered patterns of isolated nano-sized structural units formed by the self-assembling block copolymers can be used for fabricating nano-scale structural units in semiconductor, optical, and magnetic devices. Specifically, dimensions of the structural units so formed are typically in the range of 10 to 40 nm, which are sub-lithographic (i.e., below the resolutions of the lithographic tools).

Exemplary materials for the diblock copolymer layer 34 are described in commonly-assigned, U.S. Pat. No. 7,605,081 issued Oct. 20, 2009, the contents of which are incorporated herein by reference. Specific examples of self-assembling block copolymers that can be used for forming the structural units of the present invention may include, but are not limited to, polystyrene-block-polymethylmethacrylate (PS-b-PMMA), polystyrene-block-polyisoprene (PS-b-PI), polystyrene-block-polybutadiene (PS-b-PBD), polystyrene-block-polyvinylpyridine (PS-b-PVP), polystyrene-block-polyethyleneoxide (PS-b-PEO), polystyrene-block-polyethylene (PS-b-PE), polystyrene-b-polyorganosilicate (PS-b-POS), polystyrene-block-polyferrocenyldimethylsilane (PS-b-PFS), polyethyleneoxide-block-polyisoprene (PEO-b-PI), polyethyleneoxide-block-polybutadiene (PEO-b-PBD), polyethyleneoxide-block-polymethylmethacrylate (PEO-b-PMMA), polyethyleneoxide-block-polyethylethylene (PEO-b-PEE), polybutadiene-block-polyvinylpyridine (PBD-b-PVP), and polyisoprene-block-polymethylmethacrylate (PI-b-PMMA). The self-assembling block copolymers are first dissolved in a suitable solvent system to form a block copolymer solution, which is then applied onto the surface of the structure shown in FIG. 5 and then annealed to form the diblock copolymer layer 34. The solvent system used for dissolving the block copolymer and forming the block copolymer solution may comprise any suitable solvent, including, but not limited to, toluene, propylene glycol monomethyl ether acetate (PGMEA), propylene glycol monomethyl ether (PGME), and acetone. The diblock copolymer layer 34 can be formed by deposition process such as, for example, chemical solution deposition or spin-coating.

After application and annealing the self-assembling block copolymer can be converted into diblock copolymer layer 34 that includes a first polymeric block copolymer component 36 and a second block copolymer component 38, which are randomly located within the diblock copolymer layer 34. In one embodiment, each first polymeric block copolymer component 36 is comprised of roughly spherical particles of a first dimension, and each second polymeric block copolymer component 38 is comprised of roughly spherical particles of a second dimension, wherein the first dimension differs from the second dimension. Each of the first dimension and second dimension is sub-lithographic. By “roughly spherical” it is meant that the component particles assemble in an ordered or partially ordered pattern, so the particle shape enables such a pattern. The anneal mentioned above may be performed, for example, at a temperature from 200° C. to 300° C. for a duration from less than 1 hour to 100 hours.

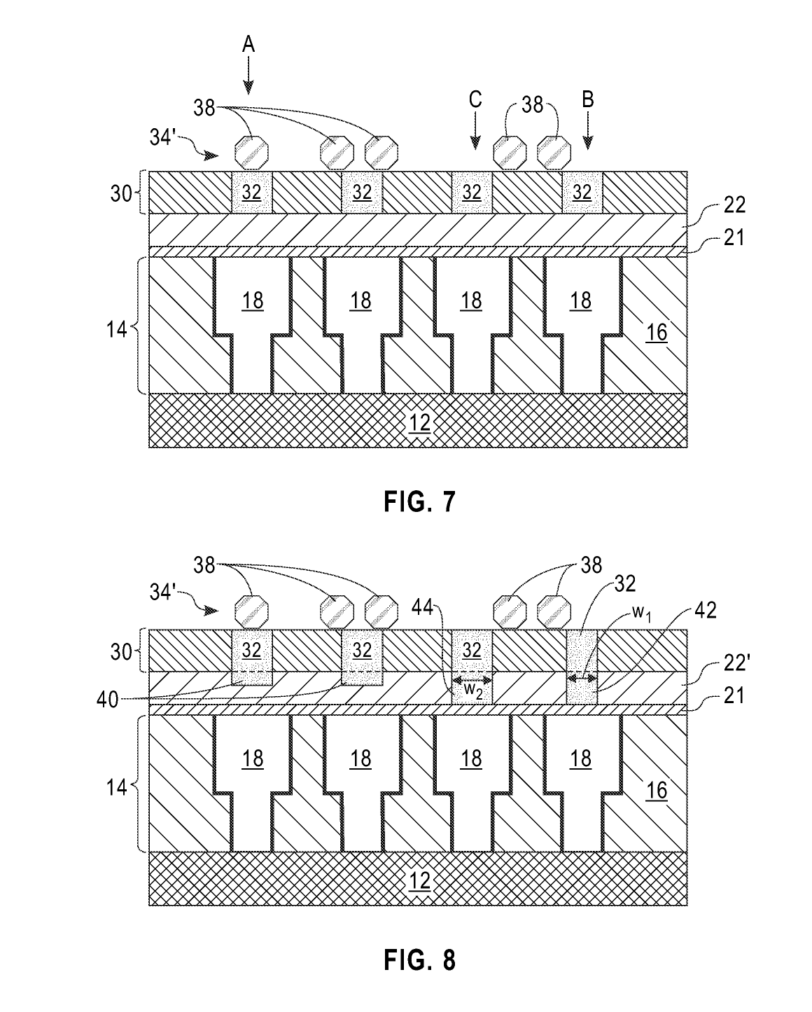

Referring now to FIG. 7, there is illustrated the structure of FIG. 6 after removing one of the polymeric block components of the diblock copolymer layer. By way of illustration and in one embodiment of the present disclosure, each of the first polymeric block components 36 is removed from the diblock copolymer layer 34. In another embodiment, each of the second polymeric block components 38 can be removed from the diblock copolymer layer 34. Notwithstanding which polymeric block component is removed, an etching process that selectively removes one of the polymeric block components relative to the other polymeric block component can be used. In one embodiment, etching in oxygen or hydrogen can be used in removing one of the polymeric block components relative to the other polymeric block component, which is not removed in the etch.

At this point of the present disclosure, the diblock copolymer layer 34 serves as a block copolymer mask 34′ which includes only one of polymeric block components which are randomly located therein. In some instances, and as shown in FIG. 7, a portion (labeled as ‘A’) of the remaining polymeric block component may completely block one of the openings within the etch mask 30, a portion (labeled as ‘B’) of the remaining block copolymer component can partially block one of the openings within the etch mask 30, and a portion (labeled as ‘C’) does not block any opening within the etch mask 30.

Referring now to FIG. 8, there is illustrated the structure of FIG. 7 after transferring the mask pattern provided by the combined block copolymer mask 34′ and the etch mask 30 into the second dielectric material 22. The transferring of the mask pattern that is provided by the combined block copolymer mask 34′ and the etch mask 30 into the second dielectric material 22 can be performed utilizing an etch process. In one embodiment, the etch process that can be used in transferring the mask patterned from the combined block copolymer mask 34′ and the etch mask 30 into the second dielectric material 22 includes fluorine.

As shown in FIG. 8, different kinds of vias can be transferred into the second dielectric material 22 during this step depending on the position of the remaining polymeric block components of the block copolymer mask 34′. In the region previously labeled as A, via 40 is partially formed into the second dielectric material 22. In the region previously labeled as B, a via 42 having a first width w₁ can be formed into the second dielectric material such that via 42 extends entirely through the second dielectric material 22 as well as entirely through the dielectric cap 21 that can be optionally present in the structure. Also, and in region previously labeled as C, a via 44 having a second width w₂ can be formed into the second dielectric material 22 such that via 44 extends entirely through the second dielectric material 22 as well as entirely through the dielectric cap 21 that can be optionally present in the structure. In accordance with the present disclosure, the first width w₁ is different from the second width w₂. Typically, and in the embodiment illustrated, the first width w₁ is less than the second width w₂. After transferring the different kinds of vias into the second dielectric material 22, the second dielectric material 22 can be referred to as patterned second dielectric material 22′. Thus these vias have different characteristic dimensions, as described above.

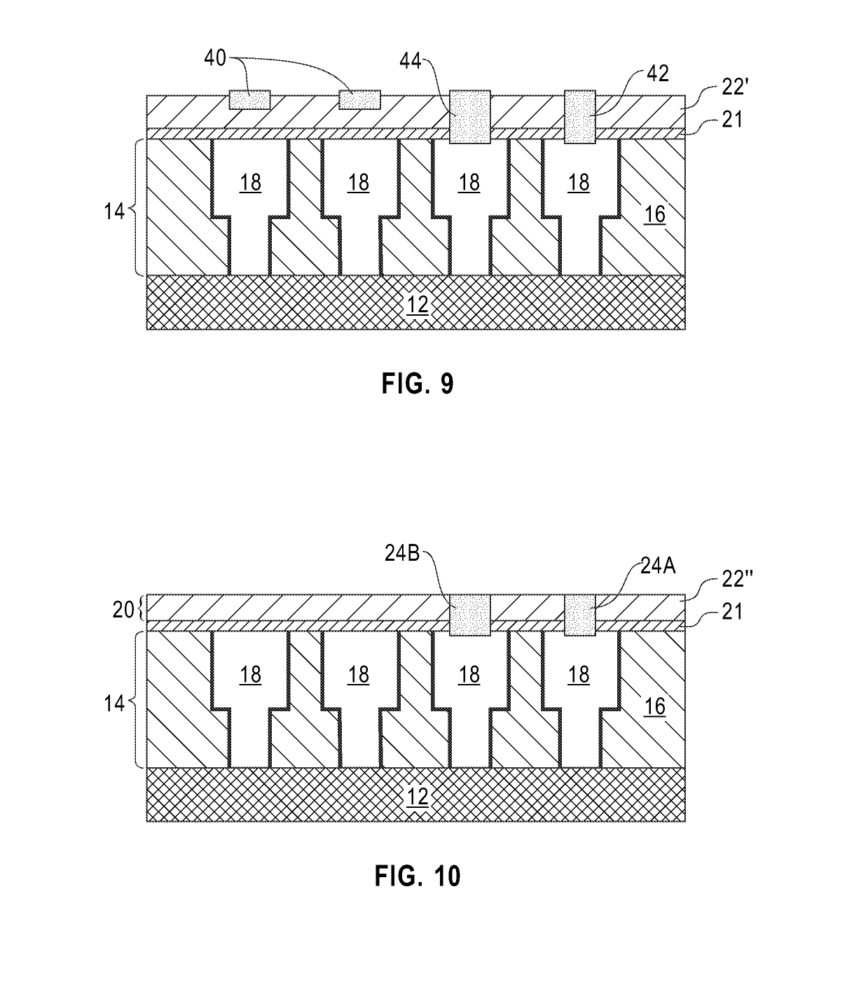

Referring now to FIG. 9, there is depicted the structure of FIG. 8 after removing the block copolymer mask 34′ including each remaining polymeric block component as well as etch mask 30 from the structure. The block copolymer mask 34′ including each remaining polymeric block component can be removed first utilizing a first etch, followed by a second etch which can be used to remove the etch mask 30. The second etch that is used to remove the etch mask 30 is typically a different etch than the first etch used to remove the block copolymer mask 34′. In one embodiment, a dilute HF etch can be used to remove the block copolymer mask 34′, while a dry etch based on fluorine can be used to remove the etch mask 30.

The resultant structure that is shown in FIG. 9 thus includes a patterned second dielectric material 22′ that has a plurality of vias 40, 42, and 44. The plurality of vias 40, 42, and 44, which can have different depths and widths (or characteristic dimension), are present randomly within the patterned second dielectric material 22′. The different depths and widths provide different dimensionally sized vias within the patterned second dielectric material 22′.

Referring now to FIG. 10, there is depicted the structure of after filling each of the vias within the patterned second dielectric material 22′ with an electrical conductive material, and planarizing the structure to remove any excess conductive material that is formed outside of the vias. The above mentioned steps of conductive material fill and planarization complete the formation of the second level 20 of the electronic structure of the present disclosure. The second level 20 of the electronic structure of the present disclosure includes a reduced thickness, patterned second dielectric material 22″ having a plurality of electrical contact vias 24A, 24B embedded therein. It is noted that electrical contact vias 24A, 24B depicted in FIG. 10 equate with the electrical contact via 24 shown in FIG. 1 of the present disclosure. By “reduced thickness” it is meant that the thickness of the patterned dielectric material after filling each of the vias with an electrical conductive material and planarization is less than the thickness of the second dielectric material prior to performing these steps. During the planarization process, vias 40 that do not extend entirely through the second dielectric material can be removed from the structure.

The electrical conductive material used in forming the electrical conductive vias 24A, 24B (and thus vias 24 in FIG. 1) includes one of the conductive materials mentioned above in forming the first regularly spaced array of conductors 18. In one embodiment, the electrical conductive material used in forming the electrical conductive vias 24A, 24B (and thus vias 24 in FIG. 1) includes a same conductive material as mentioned above in forming the first regularly spaced array of conductors 18. In another embodiment, the electrical conductive material used in forming the electrical conductive vias 24A, 24B (and thus vias 24 in FIG. 1) includes a different conductive material as mentioned above in forming the first regularly spaced array of conductors 18. The electrical conductive material that can be used in forming the electrical conductive vias within the second dielectric material can be formed utilizing one of the techniques mentioned above in forming the conductive material for the first regularly spaced apart conductors 18.

In an alternate embodiment, the electrical conductive material used in forming the electrical conductive vias 24A, 24B (and thus vias 24 in FIG. 1) includes a “reactive metal”, or RM that changes resistance in response to an applied current. In one embodiment, the reactive metal that can be present in the electrical conductive vias 24A, 24B includes a bilayered structure comprising a bottom layer of a first metal and a top layer of a second material, i.e., a metal or metal oxide. In another embodiment, the bilayered structure can be repeated N times providing a multilayered structure including N repeating bilayered structures. In this embodiment, N is an integer of greater than 2. Typically, N is from 2 to 500, with 10 to 100 being a preferred number of repeats. Examples of first metals that can be employed in this embodiment of the present disclosure include, but are not limited to, Al, Ni, Co, Fe, Zr, Y, Nd, Li, Hf, La, Ti, TiN, Ta, TaN, W, WN, MoN, Pt, Pd, Os, Ru, and mixtures or alloys of these metals and nitrides. Examples of second materials that can be used include, but are not limited to, nickel, cobalt, iron, and titanium. In some embodiments, metal oxides can be employed as the second material in a bilayered structure. Examples of metal oxides that can be employed in the present disclosure include, but are not limited to IrO₂, ReO₂, ReO₃, Cu, and oxides of Re, Ir, Cu, Fe, Ag, Co, Mn, Ni, Si, Sn, Ta, Ti, V, W, Cr, Pb, and oxide mixture or oxide alloys thereof.

The reactive metal(s) react and release heat (via an exothermic reaction) when a current pulse is applied to the structure. Any current pulse that causes an exothermic reaction within the reactive metal(s) can be employed in the present disclosure. In one typical embodiment of the present disclosure, and for a bilayered structure of Al as the bottom layer of copper oxide as the top layer, the current pulse that can used to initiate the exothermic reaction is from 1 kA/cm² to 10 MA/cm². In another typical embodiment of the present disclosure, and for a bilayered structure of Al as the bottom layer and Ni as the top layer, the current pulse that can used to initiate the exothermic reaction is from 1 kA/cm² to 10 MA/cm².

As shown in FIG. 10, a first electrical conductive via 24A is provided that has the first width w₁, while a second electrical conductive via 24B is provided that has the second width w₂. The locations of the first electrical conductive via 24A and the second electrical conductive via 24B are random, due to the method used to make said vias. Also, since the first electrical conductive via 24A has a width that is different from the width of the second electrical conductive via 24B each electrical conductive via has a different resistance associated therewith. In one embodiment, the first electrical conductive via 24A with the first width w₁ can have a resistance that is greater than the resistance of the second electrical conductive via 24B with the second width w₂.

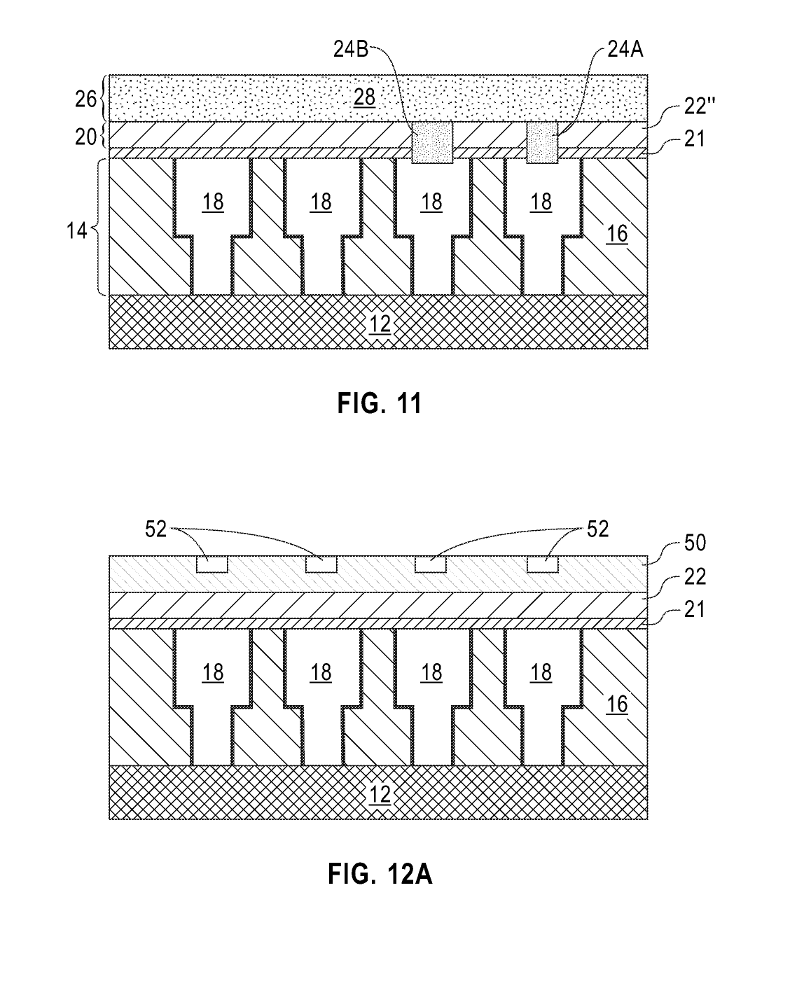

Referring now to FIG. 11, there is depicted the structure of FIG. 10 after forming the third level 26 including second regularly spaced array of conductors 28 atop the second level 20. The second regularly spaced array of conductors 28 can comprise one of the conductive materials mentioned above for the first regularly spaced array of conductors 18. In one embodiment, the second regularly spaced array of conductors 28 can comprise a same conductive material as the first regularly spaced array of conductors 18. In another embodiment, the second regularly spaced array of conductors 28 can comprise a different conductive material as the first regularly spaced array of conductors 18. The conductive material used in forming the second regularly spaced array of conductors 28 can formed utilizing one of the deposition techniques mentioned above for forming the first regularly spaced array of conductors 18. Following deposit of the conductive material, lithography and etching can be used to provide the second regularly spaced array of conductors 28 atop the second level 20. In accordance with the present disclosure the second regularly spaced array of conductors 28 are provided which are perpendicularly oriented with respect to the first regularly spaced array of conductors 18.

An energy source (not shown) may be connected to one of the first level and the third level. Examples of energy sources that can be used in the present disclosure include, but are not limited to, an off-chip battery, a power supply, a integrated miniature battery, capacitor, radioactive radiation cell, or another energy storage device integrated as part of the electronic structure. Upon detection of a tempering event, the energy source provides a current that flows through the electrical contact vias in the second level and removes electrical continuity.

In another embodiment of the present disclosure, the structure shown in FIG. 1 or FIG. 11 can be provided utilizing an alternative method. This alternative method represents a second method embodiment of the present disclosure. This second method embodiment begins by first providing the structure that is shown in FIG. 4. After providing the structure shown in FIG. 4, an electron beam sensitive coating (not shown) can be formed atop the second dielectric material 22. The electron beam sensitive coating comprises any material that is sensitive to exposure to electron beams. Examples of suitable electronic beam sensitive coatings that can be employed in the present disclosure include, but are not limited to, hydrogen silsesquioxane.

Electron beam lithography is then used to pattern the electron sensitive coating with a via array pattern including via patterns with different widths, such as, w₁ and w₂ mentioned in the previous embodiment of the present disclosure. The via patterns created in the electron beam sensitive coating are randomly oriented. Specifically, the array of via patterns can be controlled by a data file of X coordinates and Y coordinates as is known to one skilled in the art which can be inputted into a computer data base of the electron beam tool. The data file can be randomly altered based on application of a random number generator to remove via locations from the file. The array of via patterns of different widths is then transferred to the second dielectric material utilizing an etching process such as, for example, reactive ion etching. Following the transfer of the array of via patterns of different widths into the second dielectric material, the electron beam sensitive coating can be removed utilizing a conventional stripping process providing a structure similar to the one shown in FIG. 9 minus perhaps vias that do not extend entirely through the second dielectric material 22. In some embodiments, such vias can be created in this embodiment of the present disclosure as well. Processing steps as described above in conjunction with FIGS. 10-11 can then be performed to complete the fabrication of the electronic structure of the present disclosure.

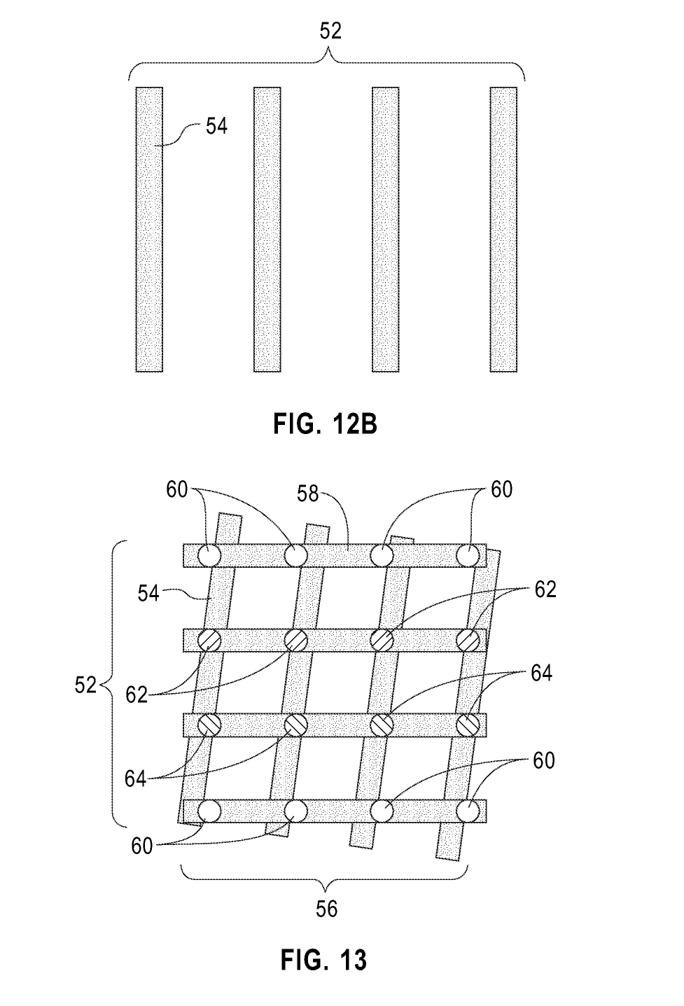

A third method embodiment can be used to form the electronic structure of the present disclosure. The third method embodiment of the present disclosure begins by first providing the structure shown in FIG. 4 of the first method embodiment. Referring now to FIG. 12A, there is depicted the structure of FIG. 4 after forming a photoresist 50 atop the second dielectric material 22 and performing a first lithographic step which creates a first pattern 52 within the photoresist 50. FIG. 12B shows a top down view of the cross sectional view depicted in FIG. 12A.

The photoresist 50 that can be employed in the present disclosure includes any organic, inorganic or hybrid photoimageable material. Following coating of the photoresist 50, the photoresist 50 is subjected to a first lithographic patterning step using a mask to form a first pattern 52 in individual first regions 54 of the photoresist 50. The first pattern 52 can be formed by exposing the photoresist to ultraviolet radiation at a first dose that is less than an optimum dose. By “optimum dose” it is meant the dose in which is typically used in lithography to pattern the photoresist. In one embodiment, and for example, the first dose is about a half of the optimum dose.

Referring now to FIG. 13, there is depicted the structure of FIGS. 12A-12B after performing a second lithographic step which creates a second pattern 56 in second individual regions 58 of the photoresist 50 using a same mask as the first lithographic step but rotated by 90°-delta, wherein delta is from 2 to 10 degrees, although other values of rotation angle may be used also. The delta is generated in the present disclosure by utilizing a random number generator. This rotation provides three different exposure regions within the photoresist 50. First region 60 denotes regions in which the first pattern 52 and the second pattern 56 do not overlap. Second region 62 denotes regions in which the first pattern 52 and the second pattern 56 partially overlap. Third region 64 denotes regions in which the first and second pattern 52, 56 overlap. At the third regions the exposed photoresist is exposed to about the optimum dose, resulting in full exposure.

The second pattern 56 can be formed by exposing the photoresist to ultraviolet radiation at a second dose which is also less than an optimum dose. In one embodiment, the first dose and the second dose add up to about the optimum dose.

The first and second patterns 52, 56 including regions 60, 62 and 64 are then transferred into the second dielectric material 22 utilizing an etching process such as reactive ion etching. After pattern transfer, photoresist 50 is stripped from the structure utilizing a conventional resist stripping process. After resist stripping, the resultant structure looks schematically similar to the structure depicted in FIG. 9 of the first method embodiment, because the plurality of vias 40, 42, and 44, which can have different depths and widths (or characteristic dimension), are present randomly within the patterned second dielectric material 22′. Processing steps as described above in conjunction with FIGS. 10-11 can then be performed to complete the fabrication of the electronic structure of the present disclosure.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. An electronic structure comprising:
a first level comprising a first regularly spaced array of conductors;
a second level comprising a plurality of electrical contact vias atop said first level; and
a third level comprising a second regularly spaced array of conductors atop said second level, wherein each electrical contact via of said plurality of electrical contact vias in said second level is individually addressed through said first regularly spaced array of conductors in said first level and said second regularly spaced array of conductors in said third level and has a resistance value, wherein each resistance value of each electrical contact via in said second level forms a distribution of resistance values, and wherein said distribution of resistance values is random.

2. The electronic structure of claim 1, further comprising at least one circuit to address and measure the resistance value of each electrical contact via.

3. The electronic structure of claim 1, wherein each electrical contact via within said second level is comprised of a material selected from the group consisting of Al, Ti, TiN, Ta, TaN, W, WN, MoN, Pt, Pd, Os, Ru, IrO₂, ReO₂, ReO₃, Cu, and mixtures or alloys thereof.

4. The electronic structure of claim 1, wherein said first regularly spaced array of conductors of the first level is oriented perpendicular to said second regularly spaced array of conductors of the third level.

5. The electronic structure of claim 1, wherein said first regularly spaced array of conductors is located within a first dielectric material, and said plurality of electrical contact vias is located in a second dielectric material.

6. The electronic structure of claim 1, wherein said each conductor of said first regularly spaced array of conductors comprises a first conductive material selected from Al, Ti, TiN, Ta, TaN, W, WN, MoN, Pt, Pd, Os, Ru, IrO₂, ReO₂, ReO₃, Cu and mixtures or alloys thereof.

7. The electronic structure of claim 1, wherein said each conductor of said second regularly spaced array of conductors comprises a second conductive material selected from Al, Ti, TiN, Ta, TaN, W, WN, MoN, Pt, Pd, Os, Ru, IrO₂, ReO₂, ReO₃, Cu and mixtures or alloys thereof.

8. The electronic structure of claim 1, wherein a first set of electrical contact vias of said plurality of electrical contact vias has a first characteristic dimension, and a second set of electrical contact vias of said plurality of electrical contact vias has a second characteristic dimension, wherein said second dimension is different from said first dimension.

9. The electronic structure of claim 1, wherein each conductor of said second regularly spaced array of conductors has a bottommost surface that is in direct electrical contact with an uppermost surface of an electrical contact via of said plurality of electrical contact vias.

10. The electronic structure of claim 9, wherein each conductor of said first regularly spaced array of conductors has an uppermost surface that is in direct electrical contact with a bottommost surface of an electrical contact via of said plurality of electrical contact vias.

11. The electronic structure of claim 1, wherein each resistance value of each electrical contact via in said second level is identified with a matrix location and the location of high and low resistance values is random.

12. The electronic structure of claim 1, wherein said each electrical contact via within said second level is comprised of a reactive metal.

13. The electronic structure of claim 12, wherein said reactive metal comprises a bilayered structure comprising a first metal and a second material, wherein first metal is selected from Al, Ni, Co, Fe, Zr, Y, Nd, Li, Hf, La, Ti, TiN, Ta, TaN, W, WN, MoN, Pt, Pd, Os, Ru, and mixtures or alloys of these metals and nitrides, and said second material is selected from Ni, Co, Fe, Ti, IrO₂, ReO₂ ReO₃, Cu, and oxides of Re, Ir, Cu, Fe, Ag, Co, Mn, Ni, Si, Sn, Ta, Ti, V, W, Cr, Pb, and oxide mixtures or oxide alloys thereof.

14. The electronic structure of claim 1, further comprising an energy source connected to said first and third levels of conductors, wherein upon detection of a tamper event a current is provided by the energy source that flows through said electrical contact vias in said second level and removes said electrical continuity.

15. An integrated circuit comprising:
at least one semiconductor device located upon a portion of a semiconductor substrate;
a first level comprising a first regularly spaced array of conductors located atop the semiconductor substrate including said at least one semiconductor device;
a second level comprising a plurality of electrical contact vias atop said first level; and
a third level comprising a second regularly spaced array of conductors atop said second level, wherein each electrical contact via of said plurality of electrical contact vias in said second level is individually addressed through said first regularly spaced array of conductors in said first level and said second regularly spaced array of conductors in said third level and has a resistance value, wherein each resistance value of each electrical contact via in said second level forms a distribution of resistance values, and wherein said distribution of resistance values is random.

16. The integrated circuit of claim 15, further comprising at least one circuit to address and read the resistance value of each electrical contact via.

17. The integrated circuit of claim 15, wherein said first regularly spaced array of conductors of the first level is oriented perpendicular to said second regularly spaced array of conductors of the third level.

18. The integrated circuit of claim 15, wherein each resistance value of each electrical contact via in said second level is identified with a matrix location and the location of high and low resistance values is random.

19. A method of forming an electronic structure comprising:
forming a first level comprising a first regularly spaced array of conductors embedded within a first dielectric material;
forming a second level comprising a plurality of electrical contact vias embedded within a second dielectric material and atop said first level, wherein said each electrical contact via of said plurality of electrical contact vias has a resistance value, wherein each resistance value of each electrical contact via forms a distribution of resistance values, and wherein said distribution of resistance values is random; and
forming a third level comprising a second regularly spaced array of conductors atop said second level, wherein each electrical contact via of said plurality of electrical contact vias in said second level is individually addressed through said first regularly spaced array of conductors in said first level and said second regularly spaced array of conductors in said third level.

20. The method of claim 19, wherein said forming the second level comprising the plurality of electrical contact vias embedded within the second dielectric material comprises:
forming a blanket layer of the second dielectric material atop the first level;
forming an etch mask containing an array of openings atop the blanket layer of the second dielectric material;
forming a diblock copolymer layer atop the etch mask, said diblock copolymer layer comprising a first polymeric block copolymer component of a first dimension and a second block copolymer component of a second dimension randomly located within the diblock copolymer layer, wherein said first dimension is different from said second dimension;
removing one of the polymeric block copolymer components from the diblock copolymer layer, while retaining the other of the polymeric block copolymer component, wherein said retained polymeric block copolymer component and said etch mask including said array of openings provide a pattern;
transferring the pattern from the retained polymeric block copolymer component and said etch mask into the blanket layer of said second dielectric material; and
removing said retained polymeric block copolymer component and said etch mask.

21. The method of claim 19, wherein a first set of the retained polymeric block copolymer component completely blocks a first set of the openings in the etch mask, a second set of the retained polymeric copolymer component partially blocks a second set of the openings in the etch mask, and wherein a third set of the retained polymeric block copolymer component does not block any of said openings in the etch mask.

22. The method of claim 19, further comprising forming a dielectric cap between said first level and said second level, wherein a portion of said dielectric cap is opened during forming said plurality of electrical contact vias in said second level.

23. The method of claim 19, wherein said first regularly spaced array of conductors of the first level is oriented perpendicular to said second regularly spaced array of conductors of the third level.

24. The method of claim 19, wherein said forming the second level comprising the plurality of electrical contact vias embedded within the second dielectric material comprises:
forming a blanket layer of the second dielectric material atop the first level;
forming an electron beam sensitive photoresist atop the blanket layer of the second dielectric material;
forming a via array pattern randomly within said electron beam sensitive photoresist utilizing electron beam lithography;
transferring the via array pattern into the blanket layer of second dielectric material; and
removing said electron beam sensitive photoresist.

25. The method of claim 24, wherein said forming the via array pattern randomly within the electron beam sensitive photoresist comprises providing a data file of X coordinates and Y coordinates, and randomly alternating the data file by utilizing a random number generator to remove some X coordinates and Y coordinates from the data file.

26. The method of claim 19, wherein said forming the second level comprising the plurality of electrical contact vias embedded within the second dielectric material comprises:
forming a blanket layer of the second dielectric material atop the first level;
forming a photoresist atop the blanket layer of said dielectric material;
forming a first pattern within individual first regions of said photoresist using a mask and a first exposure dose;
forming a second pattern second within individual second regions of said photoresist using a second exposure dose, wherein said forming the second pattern comprises rotating the mask 90°-delta, wherein delta is from 2 to 10 degrees;
transferring the first and second patterns into the second dielectric material; and
removing the photoresist.

27. The method of claim 26, wherein the forming of the first and second patterns provides a first region wherein the first and second patterns do not overlap, a second region wherein the first and second patterns partially overlap and a third region wherein the first and second patterns completely overlap.
